(19) United States
(12) Patent Application Publication
(10) Pub. No.: US 2025/0371222 A1
(43) Pub. Date: Dec. 4, 2025

(54) AUTOMATIC METHOD FOR MONITORING ROTATING PARTS OF ROTATING MACHINES BY MEANS OF DOMAIN ADAPTATION

(71) Applicant: SAFRAN, PARIS (FR)

(72) Inventors: Yosra MARNISSI, MOISSY CRAMAYEL (FR); Dany ABBOUD, MOISSY CRAMAYEL (FR); Fadi KARKAFI, MOISSY CRAMAYEL (FR); Guillaume DOQUET, MOISSY CRAMAYEL (FR); Mohammed EL BADAOUI, MOISSY CRAMAYEL (FR)

(21) Appl. No.: 18/867,280

(22) PCT Filed: May 17, 2023
(86) PCT No.: PCT/FR2023/050716

§ 371 Date: Nov. 19, 2024

(30) Foreign Application Priority Data
May 20, 2022 (FR) 2204874

(51) Int. Cl. G06F 30/27

(52) U.S. Cl. CPC G06F 30/27

(57) ABSTRACT

A method for automatically monitoring a plurality of rotating parts of rotating machines on the basis of a target database including a plurality of time signals from a distribution generated from each rotating part and on the basis of a source database including a plurality of time signals from a distribution S different from the distribution T generated from a source rotating part of a source rotating machine and being associated with an operating class, the monitoring being carried out by an adaptive deep learning model making it possible to adapt the source distribution to the target distribution, the deep learning module being trained by minimization of a cost function relating to Gaussian kernel functions having a parameter σ; σ being calculated in each period on the basis of the difference in distributions weighted by a constant static value estimated on the basis of a Pascal's triangle.

### TECHNICAL FIELD OF THE INVENTION

The technical field of the invention is that of distribution domain adaptation and deep learning transfer.

This invention relates to an automatic method for monitoring a rotating part of a rotating machine.

### TECHNOLOGICAL BACKGROUND OF THE INVENTION

In many industrial sectors, the diagnosis and monitoring of mechanical parts, such as engines and their different rotating parts (bearings, gears, shafts, fans, etc.) are essential in order to determine their state of operation or health and thus plan maintenance operations to minimise downtime. A reliable diagnostic and monitoring system or method thus enables damage to be detected and identified at an early stage, in order to prevent it spreading to other mechanical parts, and to schedule adapted maintenance based on the state of health of the part monitored. Mechanical monitoring is thus a major challenge for the mechanical engineering industry, as well as the aerospace industry in particular.

Monitoring a rotating part of a rotating machine is conventionally carried out by analysing vibratory signals generated by the rotating part and acquired by vibro-acoustic sensors, such as accelerometers, and is commonly used to determine the operating state of aircraft engines and their rotating parts. During production or maintenance phases, high-frequency vibratory signals are acquired when the rotating machine is in operation, in order to detect weak signals characteristic of damage to a mechanical part, known as signatures, and thus prevent engine failure. Monitoring by analysing vibratory signals is one of the most widely used methods because of its non-intrusive nature and the wealth of diagnostic information that vibratory signals can provide.

Conventionally, vibration diagnosis methods are based on signal processing methods using vibratory signals. The signals are input to a processing task comprising processing methods (source separation, filtering, denoising, etc.) with the aim of extracting or improving a “vibratory signature” of interest and associating it with a mechanical part. Vibration analysis therefore consists in inferring the state of health of a rotating mechanical part through its vibratory signature, this inference requiring a priori kinematic knowledge, as well as a monitoring expert. Subsequently, appropriate indicators can be constructed to quantify the damage and facilitate decision-making.

Monitoring and diagnostic methods based on artificial intelligence are currently being increasingly developed. The main aim of these methods is to replace human knowledge required in traditional approaches with machine learning based on an abundance of data.

In this context, intelligent fault diagnosis (IFD) is emerging as an auxiliary or alternative solution to the “signal processing” approach already discussed. With the rapid development of deep learning, intelligent fault diagnosis has shown significant interest in recent years.

The success of a deep learning model depends on both the choice of architecture for the model and the representativeness and abundance of the training data. For example, in the case concerned with bearing monitoring, signals from healthy bearings with each type of fault are required to train the model so that it can analyse new bearings and classify their state. The success of IFD approaches is subject to a common hypothesis: there is sufficient labelled data to form reliable diagnostic models.

In aerospace, however, it is difficult to collect sufficient labelled data due to the rarity of faults. As a result, unlabelled data from real machines cannot train diagnostic models to provide accurate results. In addition, the difference in acquisition context between the training signals in existing databases and the signals to be classified affects performance of the learning models because two signals acquired in two different contexts are derived from two different probability distributions.

Domain adaptation is a tool for reusing knowledge learned from a set of signals acquired from a rotating machine in a first context, this set of data is called the source domain, by transferring it to analyses of related signals, acquired for the same type of rotating machine but in a different context: this group of data is called the target domain. The source domain represents a set of data that have already been acquired and labelled, i.e. their operating class is known.

In order to reuse source databases for the diagnostic tasks of a target database, deep transfer learning models, considering parameters to be set, especially for the cost function of the model, are used because of their efficiency and ability to reduce the large difference in distribution between the source and target domains. On the other hand, the state of health of the mechanical part being monitored is unknown. The data from the target domain are therefore naturally unlabelled. Therefore, the main problem amounts to being able to adjust parameters of the deep learning model without having to rely on the labels of the operating state of the rotating machine to identify whether the model has correctly predicted its current state.

### SUMMARY OF THE INVENTION

The invention offers a solution to the problems previously discussed, by making it possible to carry out automatic monitoring of a rotating part, the operating class of which is unknown, from a deep transfer learning model on a source and target database by adjusting parameters relating to the learning model independently of the labels of the target database.

A first aspect of the invention relates to a method for automatically monitoring at least one rotating part of a rotating machine, from an unlabelled database referred to as the target database comprising at least one time signal derived from a distribution T, the time signal being generated from the rotating part, and from a source database comprising a plurality of time signals derived from a distribution S different from the distribution T, each time signal of the source database being generated from a source rotating part of a source rotating machine and being associated with an operating class from a set of operating classes comprising at least a nominal operating class and a faulty operating class, the method being characterised in that it comprises the following steps of:
Training a first trained neural network capable of associating an operating class from the set of operating classes with a non-stationary time signal derived from the distribution S, the first neural network comprising a first part for characteristic extraction, and a second part for classification, the artificial neural network being trained based on source data,
Training a so-called adaptive artificial neural network according to a number of training epochs M, in order to obtain a trained artificial neural network capable of associating a class from the set of operating classes with a time signal derived from an S and T union distribution, the adaptive neural network comprising a first part for characteristic extraction, corresponding to the first part of the first neural network, and a second part for adapting the distribution S to the distribution T and for classification, the artificial neural network being simultaneously trained on the source and target databases, training being performed by minimising a cost function comprising:
   a first term corresponding to the error between the class obtained by the neural network for each signal of the source database and the class associated with said signal of the source database;
   a second term calculated from at least one maximum mean discrepancy between a function of the source database and a function of the target database, the maximum mean discrepancy being calculated from at least one Gaussian kernel function of the parameter o, the parameter o being estimated from a Pascal's triangle, the parameter o being relative to a variance of the Gaussian kernel function and being dependent on each training epoch, the Gaussian kernel function, of the order \sqrt{Lₘₐₓ} being determined from the last row of a Pascal's triangle of the size \sqrt{Lₘₐₓ}:
Using the adaptive artificial neural network trained for each signal in the target database, in order to associate an operating class with said signal.

The target domain D_{T} is defined such that D_{T}={X, T=P_{T}(X^{T})}; where X is a space of signal characteristic descriptors, T=P(X^{T}) is the marginal probability distribution and X_{T}∈X.

The source domain D_{S} is defined such that D_{S}={X, S=P_{S}(X^{S})}; where X is a space of signal characteristic descriptors, S=P(X^{S}) is the marginal probability distribution and X_{S}∈X.

By “distribution S different from distribution T”, it is meant P_{S}(X^{S})≠P_{T}(X^{T}).

In particular, the adaptation from distribution S to distribution T is achieved by minimising the second term of the cost function, which is calculated from the source database from distribution S and the target database from distribution T. The aim of adapting the domain is to reduce discrepancy between the distributions of both source and target databases (during or after training) so that the classification of the target database is almost identical to that of the source. The two databases deal with the same subject (bearing faults in the rotating machine, for example) but each relates to different operating conditions of the rotating machine (rotation speeds, load, torque, etc.). In particular, the Maximum Mean Discrepancy (MMD) is, for example, one of the most effective functions, based on minimising the maximum discrepancy between the distributions, to minimise discrepancy between the distributions and therefore perform adaptation between domains.

Thus the first part of the adaptive artificial neural network is one and the same as the first part of the first neural network before the adaptive artificial neural network is trained. The architecture and parameters of the first part of the artificial neural network are identical to the architecture and parameters of the first part of the first neural network. The architecture of a neural network (or part of the network) corresponds to the number of layers, neurons and their arrangement. In other words, the first part of the artificial neural network and the first part of the first neural network are identical.

The invention advantageously makes it possible to classify signals from an unlabelled target database, the state of the rotating machine therefore being unknown under the conditions of acquisition of the signals of distribution T, in one class of a set of classes, from a labelled source database, the signals from the source database having a different distribution from the distribution of the signals from the target database, by virtue of a parameter o depending on a Pascal's triangle, without requiring adjustment from missing labels from the target database. Indeed, since the cost function of the neural network is partly minimised by virtue of a Gaussian kernel function, the last row of a Pascal's triangle advantageously enables a Gaussian kernel function of the same size as the last row to be represented as the triangle, the size being chosen according to the source and target databases, for example, and therefore its parameters to be determined, without any additional external adjustment. Thus, the invention makes it possible to carry out automated monitoring of rotating parts of rotating machines, by virtue of signals from a T distribution without associated labels, without the intervention of an expert, and thus saves time when maintaining rotating machines.

The Gaussian kernel for calculating the parameter σ (and therefore the cost function) is introduced with the aim of reducing difference in the distributions of the databases, both relative to each other and within each database itself. So, using the same kernel to reduce this difference each time is not very efficient since it changes each time the model adjusts its weights (i.e. at each training epoch). Consequently, the Gaussian kernel has to be defined during each iteration to update the pattern of this reduction. On the other hand, the parameter defining the Gaussian kernel being its variance or equivalently its standard deviation, which in this case is denoted by σ, σ is therefore dependent on the difference in the distributions so that it changes respectively.

Thus, as the parameter o varies according to each training epoch, during which the distributions are brought closer together, the estimation of this parameter is well robust to the variance relative to the difference in the distributions.

Advantageously, the second term of the cost function and in particular the maximum mean discrepancy is a dynamic value which varies at each training epoch. Advantageously, no trial and error or adjustments are made by an operator

to find the best variance (or equivalently standard deviation) of the Gaussian kernel.

Further to the characteristics just discussed in the preceding paragraph, the method according to a first aspect of the invention may have one or more additional characteristics from among the following, considered individually or according to any technically possible combinations:
the first part of the adaptive neural network comprises a number of layers N_{c1}, N_{c1} being a natural number greater than or equal to 1, and in that the second part of the adaptive neural network comprises a number of layers N_{c2}, N_{c2} being a natural number greater than or equal to 1, the second term of the cost function being calculated on one or more layers belonging to the second part of the neural network, and situated before a last layer of the second part. In particular, on each layer of a set of layers (situated before the last layer) of the second part, a maximum mean discrepancy is calculated. The second term of the cost function thus comprises the sum of each maximum mean discrepancy calculated. The last layer is a decision layer for classifying the input signal into an operating class, after the distributions in the layer(s) preceding the last layer have been brought closer together.
monitoring is carried out for a plurality of nr rotating machine parts and in that the target database comprises a plurality of signals envieu by

$${X}^{T} = {\{ {X}_{j}^{T} \}}_{1 \leq j \leq nT .}$$

the plurality of signals of the source database is denoted by

$${X}^{S} = {\{ {X}_{j}^{S} \}}_{1 \leq j \leq nS}$$

and the second term of the cost function is calculated at each epoch from the function Σ_{P≥p≥1} Σ_{m∈Ncc} MMDₚ (f^{m}(X^{S}), f^{m}(X^{T})), the set of signals f^{m}(X^{S})={f^{m}(X_{S})}_{1≤i≤ns} representing the output of the m^{th} layer of the adaptive artificial neural network for an input X^{S}, each signal

$${f}^{m} ( {X}_{i}^{S} )$$

having a length L_{mS}, and the set of signals f^{m}(X^{T})={f^{m}(Xⱼ^{T})}_{1≤j≤nT} representing the output of the m^{th} layer of the adaptive artificial neural network for an input X^{T},

$${f}^{m} ( {X}_{j}^{T} )$$

having a length L_{mT}, m being an interger included in a set Ncc comprising each layer number of the second part from which a maximum mean discrepancy is calculated, with:

$${MMD}_{P} ( {f}^{m} ( {X}^{S} ) , {f}^{m} ( {X}^{T} ) ) = \frac{1}{{n}_{s}^{2}} {\sum }_{i = 1}^{{n}_{s}} {\sum }_{j = 1}^{{n}_{s}} {k}_{p} ( {f}^{m} ( {X}_{i}^{s} ) , {f}^{m} ( {X}_{j}^{s} ) ) + \frac{1}{{n}_{T}^{2}} {\sum }_{i = 1}^{{n}_{T}} {\sum }_{j = 1}^{{n}_{T}} {k}_{p} ( {f}^{m} ( {X}_{i}^{T} ) , {f}^{m} ( {X}_{j}^{T} ) ) - \frac{2}{{n}_{s} {n}_{T}} {\sum }_{i = 1}^{{n}_{s}} {\sum }_{j = 1}^{{n}_{T}} {k}_{p} ( {f}^{m} ( {X}_{i}^{s} ) , {f}^{m} ( {X}_{j}^{T} ) ) ,$$

With:

$${k}_{p} ( {f}^{m} ( {X}_{i}^{s} ) , {f}^{m} ( {X}_{j}^{s} ) ) = {e}^{\frac{- {\vert {f}^{m} ( {X}_{i}^{s} ) - {f}^{m} ( {X}_{j}^{s} ) \vert}^{2}}{2 {σ}_{nSS ( p )}^{2}}}$$

where σ_{mSS}(p) is the variance of the Gaussian kernel function kₚ relating to the set f^{m}(X^{S}),

$${k}_{p} ( {f}^{m} ( {X}_{i}^{T} ) , {f}^{m} ( {X}_{j}^{T} ) ) = {e}^{\frac{- {\vert {f}^{m} ( {X}_{i}^{T} ) - {f}^{m} ( {X}_{j}^{T} ) \vert}^{2}}{2 {σ}_{mTT ( p )}^{2}}}$$

where σ_{mTT} (p) is the variance of the Gaussian kernel function kₚ relating to the set f^{m}(X^{T})

$${k}_{p} ( {f}^{m} ( {X}_{i}^{s} ) , {f}^{m} ( {X}_{j}^{T} ) ) = {e}^{\frac{- {\vert {f}^{m} ( {X}_{i}^{S} ) - {f}^{m} ( {X}_{j}^{T} ) \vert}^{2}}{2 {σ}_{mST ( p )}^{2}}}$$

with σ_{mST} (p) the variance of the Gaussian kernel function kₚ relating to the set f^{m}(X^{S}) and the set f^{m}(X^{T}),
P being a natural number greater than or equal to 1, each vector [σ_{mSS} (p)]_{p≥1} being denoted by σ_{mSS}, each vector [σ_{mTT} (p)]_{p≥1} being denoted by σ_{mTT}, each vector [σ_{mST} (p)]_{p≥1} being denoted by σ_{mST} and each matrix

$$( \begin{matrix}{σ}_{mSS} \\ {σ}_{mTT} \\ {σ}_{mST}\end{matrix} )$$

being denoted by σₘ, the parameter σ being equal to the set {σₘ} _{m∈Ncc}. Advantageously, the number P of Gaussian kernel functions kₚ makes it possible to increase the calculation accuracy of the function Σ_{N≥p≥1} Σ_{m∈Ncc} MMDₚ(f^{m}(X^{S}), f^{m}(X^{T})) function and therefore the training cost function of the adaptive artificial neural network. In particular, during each training epoch, the distributions of S and T vary. Thus, at each epoch, the parameter σₘ for calculating the second term of the cost function (and comprising three components) also varies to correspond to the new distributions. Thus, the three components vary at each epoch to adapt to the variations in the distributions S and T.
the step of training the adaptive neural network is carried out according to a number of epochs M, and for each epoch of the number of epochs M, the parameter σ={σm} _{m∈Ncc} is estimated in the following sub-steps of:
   For each layer m ∈ Ncc:
      Determining Lₘₐₓ, Lₘₐₓ being the maximum length between the length of each signal of the set

$${\{ {f}^{m} ( {X}_{i}^{S} ) \}}_{1 \leq j \leq {n}_{S}}$$

and each signal of the set

$${\{ {f}^{m} ( {X}_{j}^{T} ) \}}_{1 \leq j \leq {n}_{T}} .$$

Resampling each signal

$${f}^{m} ( {X}_{i}^{S} )$$

into a two-dimensional image Im_{m,i}^{S} of the size \sqrt{Lₘₐₓ}*\sqrt{Lₘₐₓ} and resampling each signal

$${f}^{m} ( {X}_{j}^{T} )$$

into a two-dimensional image Im_{m,j}^{T} of the size \sqrt{Lₘₐₓ}*\sqrt{L_{max,}}
Determining the variance

$${σ}_{\sqrt{{L}_{m ax}}}$$

of a Gaussian kernel function of the order \sqrt{Lₘₐₓ} in the following sub-steps of:
Constructing a matrix Ng_{√Lmax} representing a Gaussian kernel of the order \sqrt{L_{max,}} the matrix Ng_{√Lmax} is equal to: 2^{(1-√Lmax)}*^{t}TP_{√Lmax}*TP_{√Lmax}*2^{(1-√Lmax)}, TP _{√Lmax} representing the last row of a Pascal's triangle of the order \sqrt{Lₘₐₓ} and ^{t}TP _{√Lmax} being the transpose of TP _{√Lmax},
Calculating the variance

$${σ}_{\sqrt{{L}_{m ax}}}$$

from the formula:

$$\sqrt{\frac{1}{2 π * max ( {Ng}_{\sqrt{L} m ax} )}} ,$$

max (Ng_{√Lmax} ) being equal to the maximum value of the matrix Ng_{√Lmax} ,
Calculating a vector

$$( \begin{matrix}{σ}_{SS} \\ {σ}_{TT} \\ {σ}_{ST}\end{matrix} )$$

according to the following sub-steps:
Calculating σ_{SS} from

$$\frac{1}{{n}_{s}^{2}} {\sum }_{i = 1}^{n s} {\sum }_{j = 1}^{n s} {( I {m}_{m , i}^{S} - I {m}_{m , j}^{S} )}^{2} ,$$

Calculating σ_{TT} from

$$\frac{1}{{n}_{T}} {\sum }_{i = 1}^{nT} {\sum }_{j = 1}^{nT} {( I {m}_{m , i}^{T} - I {m}_{m , j}^{T} )}^{2}$$

Calculating σ_{ST} from

$$\frac{1}{{n}_{s} {n}_{T}} {\sum }_{i = 1}^{n s} {\sum }_{j = 1}^{nT} {( I {m}_{m , i}^{S} - I {m}_{m , j}^{T} )}^{2}$$

Calculating σₘ according to the following formula.

$${σ}_{m} = {σ}_{\sqrt{{L}_{ma x}}} * ( \begin{matrix}{σ}_{S S} \\ {σ}_{T T} \\ {σ}_{S T}\end{matrix} ) .$$

Advantageously, the signals are resampled and converted into images in order to save calculation time. In addition, the parameter σ is estimated by virtue of both source and target databases and the Pascal's triangle, without requiring labels for the target database to be classified. The components σ_{SS}, σ_{TT} and σ_{ST} of σₘ are calculated at each training epoch because they depend on the difference in distribution, which changes during each training epoch.

$${σ}_{\sqrt{{L}_{m ax}}}$$

is a static reference value (in other words: this value does not vary as a function of the training epochs) and is used to evaluate the change after each training epoch and therefore each adjustment to the parameters (or weights) of the adaptive neural network.
According to one embodiment:

$${σ}_{SS} = \frac{1}{{n}_{s}^{2}} {\sum }_{i = 1}^{n s} {\sum }_{j = 1}^{n s} {( I {m}_{m , i}^{S} - I {m}_{m , j}^{S} )}^{2} ⋆ [ \begin{matrix}1 & 2 & 4 & 8 & … & {2}^{P - 1}\end{matrix} ] ,$$

each coefficient σ_{SS}(p) being equal to

$${2}^{p - 1} * \frac{1}{{n}_{s}^{2}} {\sum }_{i = 1}^{n s} {\sum }_{j = 1}^{n s} {( I {m}_{m , i}^{S} - I {m}_{m , j}^{S} )}^{2} ,$$

$${σ}_{TT} = \frac{1}{{n}_{T}^{2}} {\sum }_{i = 1}^{n s} {\sum }_{j = 1}^{n T} {( I {m}_{m , i}^{T} - I {m}_{m , j}^{T} )}^{2} ⋆ [ \begin{matrix}1 & 2 & 4 & 8 & … & {2}^{P - 1}\end{matrix} ] ,$$

each coefficient σ_{TT}(p) being equal to

$${2}^{p - 1} * \frac{1}{{n}_{T}^{2}} {\sum }_{i = 1}^{n s} {\sum }_{j = 1}^{n T} {( I {m}_{m , i}^{T} - I {m}_{m , j}^{T} )}^{2} .$$

$${σ}_{ST} = \frac{1}{{n}_{S} {n}_{T}} {\sum }_{i = 1}^{n s} {\sum }_{j = 1}^{n T} {( I {m}_{m , i}^{S} - I {m}_{m , j}^{T} )}^{2} ⋆ [ \begin{matrix}1 & 2 & 4 & 8 & … & {2}^{P - 1}\end{matrix} ] ,$$

each coefficient σ_{ST}(p) being equal to

$${2}^{p - 1} * \frac{1}{{n}_{S} {n}_{T}} {\sum }_{i = 1}^{n s} {\sum }_{j = 1}^{n T} {( I {m}_{m , i}^{S} - I {m}_{m , j}^{T} )}^{2} .$$

P is equal to 5. The higher P, the more accurate the estimate of the parameter. Increasing the order has a drawback from the point of view of the resources available to carry out calculations. Advantageously, P equal to 5 makes it possible to obtain a compromise between a correct estimate of σ and reduced calculation time.

A third aspect of the invention relates to a computer program product comprising instructions which, when the program is executed on a computer, cause the same to implement the steps of the method according to a first aspect of the invention and the method according to a second aspect of the invention.

The invention and its different applications will be better understood upon reading the following description and upon examining the accompanying figures.

### BRIEF DESCRIPTION OF THE FIGURES

The figures are set forth by way of indicating and in no way limiting purposes

of the invention.

FIG. 1 shows a block diagram of a method for monitoring a rotating part of rotating machine according to the invention.

FIG. 2 represents resampling of a time signal into a two-dimensional image.

FIG. 3 represents a Gaussian kernel of the size 28×28.

### DETAILED DESCRIPTION

The figures are set forth by way of indicating and in no way limiting purposes of the invention.

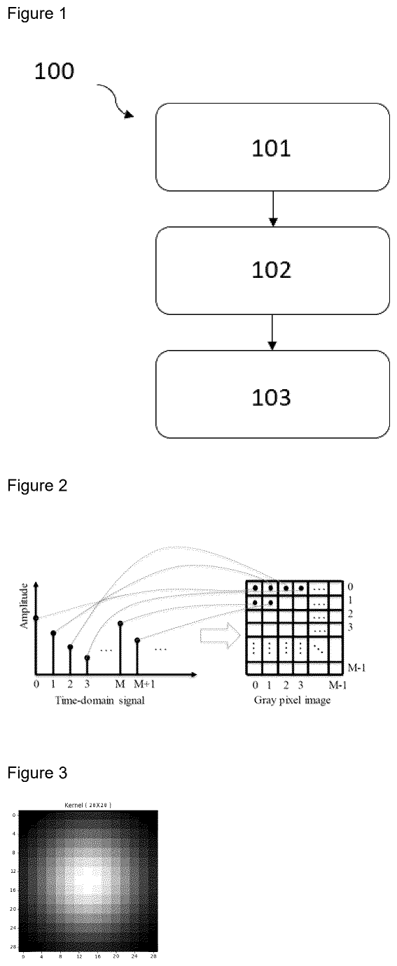

FIG. 1 shows a schematic representation of a block diagram of a method 100 for automatically monitoring at least one rotating part of a rotating machine, from a “target” database comprising at least one time signal from a distribution T and generated from the rotating part, and using a source database comprising a plurality of time signals from a distribution S different from the distribution T.

The rotating machine is, for example, an engine, preferably an aircraft turbojet engine.

For example, the rotating part of the rotating machine is one or more mechanical shafts, one or more bearings, one or more fans, one or more turbines or one or more compressors.

According to one embodiment, monitoring is carried out for a plurality of n_{T} rotating parts of rotating machines and in that the target database comprises a plurality of signals denoted by

$${X}^{T} = {\{ {X}_{j}^{T} \}}_{1 \leq j \leq {n}_{T}} ,$$

n_{T} being a natural number greater than 1.

The n_{T} rotating parts are of the same type, thus the n_{T} rotating parts are bearings, for example.

Each time signal

$${X}_{j}^{T}$$

is generated from one motaung part from the n_{T} rotating parts.

Each time signal can be a non-stationary time signal. By “non-stationary time signal”, it is meant a physical time signal whose frequency content varies over time.

In the remainder of this document, the terms “time signal” or “signal” will be used interchangeably. In the remainder of this document, the terms “target database signal” or

“target signal” will be used interchangeably.

Each target signal is preferably generated from vibrations of a so-called target rotating part of a so-called target rotating machine.

For example, each target signal is measured using a sensor, possibly on board a target rotating machine, for example a vibro-acoustic sensor. The vibro-acoustic sensor is for example an accelerometer, a strain gauge or a microphone.

Each target signal comprises a number L_{T} of points, wherein the number L_{T} can be dependent on the sampling frequency of the sensor.

According to one preferred embodiment, each target signal is a vibratory signal.

The plurality of target signals is denoted by

$${X}^{T} = {\{ {X}_{j}^{T} \}}_{1 \leq j \leq {n}_{T}} ,$$

where n_{T} is a non-zero natural number representing the number of target signals in the target database.

Each non-stationary time signal from a distribution T is a signal generated from vibrations of the rotating part of the rotating machine in a context T′.

The target domain D_{T} is defined as D_{T}={X, T=P_{T}(X_{T})}; where X is a space of signal characteristic descriptors, T=P(X^{T}) is the marginal probability distribution and X_{T}∈X.

A context corresponds to the operating conditions of a rotating machine, for example the values of parameters relating to the rotating machine. A parameter relating to the rotating machine may be the speed of rotation of the rotating machine, load, temperature of the rotating machine, type of rotating machine, or position of the vibro-acoustic sensor in the rotating machine.

The plurality of source signals is denoted by

$${X}^{S} = {\{ {X}_{i}^{S} \}}_{1 \leq i \leq nS} ,$$

where n_{S} is a non-zero natural number representing the number of source signals in the source database. The source database comprises ns signals generated from ns source rotating parts of source rotating machines.

Each time signal of the source database is generated from a source rotating part of a source rotating machine and is associated with an operating class from a set of operating classes. Preferably, each signal of the source database is generated from vibrations of the source rotating part.

A database in which each signal is associated with one of a set of classes is said to be “labelled”. Thus, the source database is labelled.

In the following, the terms “source database signal” or “source signal” will be used interchangeably.

Each source signal is measured, for example, using a sensor, possibly on board a source rotating machine, for example a vibro-acoustic sensor. The vibro-acoustic sensor is for example an accelerometer, a strain gauge or a microphone.

Each source rotating part is of the same type as each rotating part, i.e. if each rotating part is a bearing, each source rotating part is a bearing.

Each source signal comprises a number Ls of points, wherein the number Ls can be dependent on the sampling frequency of the sensor.

Each source rotating machine is of the same type as each target rotating machine, i.e. if each target rotating machine is an aircraft engine, each source rotating machine is also an aircraft engine.

The natural number n_{S} may be equal to or different from the natural number n·_{T}

Two signals come from a same distribution if, during their acquisition, the value of a single parameter relating to the rotating machine varies.

Each non-stationary time signal derived from the distribution S is a signal generated from vibrations of the rotating part of the rotating machine in a context S′.

The source domain D_{S} is defined such that D_{S}={X, S=P_{S}(X_{S})}; where X is the space of signal characteristic descriptors, S=P_{S}(X_{S}) is the marginal probability distribution and X_{S}∈X.

The contexts S′ and T′ are different.

If two signals are acquired in two different contexts, at least two parameters relating to the rotating machine have different values and both signals have different distributions.

When two signals are acquired in two different contexts, their domains are considered to have different distributions. The domains D_{S} and D_{T} are thus considered to have different distributions.

By “domains D_{S} and D_{T} have different distributions”, it is meant: X_{S}=X_{T} and P_{S}(X_{S})≠Pₜ(Xₜ) (and therefore S≠T).

For example, a set of signals comprising a first, second and third signal is measured by a sensor attached to a same rotating machine. Each signal is measured on the same type of rotating machine, at the same temperature of the rotating machine and at the same position of the rotating machine, the only parameter whose value varies is the speed of rotation of the rotating machine, denoted by N2. The first signal is measured at N2=600 rpm, the second signal is measured at N2=800 rpm and the third signal is measured at N2=1000 rpm. The first, second and third signals are measured in a same context and form part of a same distribution.

For example, a first signal and a second signal are measured by a sensor attached to an. The first signal is measured for a speed N2=600 rpm and for a load equal to 1 HP, the second signal is measured for a speed N2=800 rpm and for a load equal to 3 HP. Two parameters relating to the rotating machine have different values when the first signal and the second signal are acquired, thus the first and second signals do not come from the same distribution.

The set of operating classes is a set of operating classes for the rotating part.

For example, the set of operating classes for the rotating part comprises at least the following classes: nominal operating class and faulty operating class.

For example, the set of operating classes for the rotating part comprises the following classes: nominal operating class, operating class with a first fault, operating class with a second fault, operating class with a third fault. A first fault may be a wear fault, for example. A second fault may be a scaling fault, for example.

According to one embodiment, the method 100 may comprise a first step 101 of supervised training of a first artificial neural network in order to obtain a trained artificial neural network capable of providing, from a signal belonging to the distribution S, a class included in the set of operating classes.

Supervised training, otherwise known as supervised learning, enables an artificial neural network to be trained for a predefined task, by updating its parameters in such a way as to minimise a cost function corresponding to the error between the output data supplied by the artificial neural network and the true output data, i.e. what the artificial neural network should provide as output to fulfil the predefined task from some input data.

The artificial neural network preferably comprises a first, characteristic extraction, part and a second, classification, part.

The first part preferably comprises a set of convolutional artificial neuron layers and a set of so-called pooling artificial neuron layers, each pooling artificial neuron layer being preceded by a convolutional artificial neuron layer and followed by a convolutional artificial neuron layer. For example, the first part performs extraction of health indicators from the rotating machine and is trained so as to properly extract (by virtue of a cost function) the characteristics of these health indicators.

The first part comprises a number of layers N_{c1}, N_{c1} being a natural number greater than or equal to 1 and preferably equal to 4.

Supervised training of the first artificial neural network consists in updating the parameters of the first artificial neural network so as to minimise a cost function corresponding to the error between the prediction of the class provided by the artificial neural network from a source signal of the source database and the class associated with said source signal of the source database.

The cost function is, for example, a root mean square function or a cross-entropy function.

The cost function is minimised, for example, using a stochastic gradient descent algorithm with Back-Propagation Through Time (BPTT).

The first neural network is trained according to a number of epochs B, where B is a natural number greater than 1.

The method 100 comprises a step 102 of training a so-called adaptive artificial neural network in order to obtain an artificial neural network trained capable of associating a class from the set of classes with a non-stationary time signal derived from an S and T union distribution. A non-stationary time signal derived from an S and

T union distribution is a signal that can be derived from the distribution S or the distribution T.

The adaptive artificial neural network is simultaneously trained on the source database and the target database.

The adaptive neural network comprises a first, characteristic extraction, part and a second part for so-called domain adaptation and classification.

Preferably, the first part of the adaptive neural network is one and the same as the first part of the first neural network before beginning training of the adaptive neural network begins. Thus, the first part of the adaptive neural network comprises a number of layers N_{c1}, N_{c1} being a natural number greater than or equal to 1 and preferably equal to 4.

Preferably, the second part of the adaptive neural network comprises a set of so-called “fully-connected” layers.

Preferably, the second part of the adaptive artificial neural network comprises a number of layers N_{c2}, N_{c2} being a natural number greater than or equal to 1 and preferably equal to 4 or 5 for example.

In the following, notation f^{m}(X^{S}) represents the output of the m^{th} layer of the adaptive artificial neural network for an input X^{S}, and f^{m}(X^{T}) represents the output of the m^{th} layer of the adaptive artificial neural network for an input X^{T}, where m is a natural number included in the interval [symbol] 1, N_{c1}+N_{c2} [symbol] .

The set f^{m} (X^{S}) is equal to

$$\{ {{f}_{m} ( {X}_{i}^{S} )}_{1 \leq i \leq nS} .$$

Each element

$${f}^{m} ( {X}_{i}^{S} )$$

of the set f^{m} (X^{S}) is a signal with a number of points Lₘₛ, where Lₘₛ is a non-zero natural number.

The set f^{m}(X^{T}) is equal to

$${\{ {f}^{m} ( {X}_{j}^{T} ) \}}_{1 \leq j \leq nT} .$$

Each element

$${f}^{m} ( {X}_{j}^{T} )$$

of the set f^{m} (X^{T}) is a signal with a number of points L_{mT}, where L_{mT} is a non-zero natural number.

The integers Lₘₛ and L_{mT} may be equal or different.

In the following, the expressions “number of points in a signal” and “length of a signal” will be one and the same.

The adaptive neural network is trained according to a number of epochs M, where M is an integer greater than or equal to 1, by minimising a cost function relating to the adaptive artificial neural network at each epoch.

In the following, the expressions “cost function relating to the adaptive artificial neural network” and “adaptive cost function” will be one and the same.

The adaptive cost function is minimised, for example, using a stochastic gradient descent algorithm with back-propagation through time (BPTT).

The cost function comprises at least a first term and a second term.

The first term of the cost function is proportional to the error between the class prediction provided by the adaptive artificial neural network from a source signal of the source database and the class, from among the set of function classes {yᵢ}_{i≥1,} associated with said source signal of the source database.

The second term of the cost function is calculated from at least the sum of each maximum mean discrepancy (MMD) calculated at the output of at least one layer of the second part, for the source database and the target database input to the adaptive neural network.

The second term is calculated using the following formula:

$${\sum }_{P \geq p \geq 1} {\sum }_{m ∈ Ncc} {MDD}_{p} ( {f}^{m} ( {X}^{S} ) , {f}^{m} ( {X}^{T} ) )$$

The index m belongs to a set Ncc comprising each layer number of the second part selected and from which a maximum mean discrepancy is calculated. Ncc may comprise a single layer number or a number of layer numbers greater than 1 and strictly less than N_{c1}+N_{c2}.

The formula of MMDp(f^{m} (X^{S}), f^{m} (X^{T})) is as follows:

$${MMD}_{p} ( {f}^{m} ( {X}^{S} ) , {f}^{m} ( {X}^{T} ) ) = \frac{1}{{n}_{s}^{2}} {\sum }_{i = 1}^{{n}_{s}} {\sum }_{j = 1}^{{n}_{s}} {k}_{p} ( {f}^{m} ( {X}_{i}^{s} ) , {f}^{m} ( {X}_{j}^{s} ) ) + \frac{1}{{n}_{T}^{2}} {\sum }_{i = 1}^{{n}_{T}} {\sum }_{j = 1}^{{n}_{T}} {k}_{p} ( {f}^{m} ( {X}_{i}^{T} ) , {f}^{m} ( {X}_{j}^{T} ) ) - \frac{2}{{n}_{s} {n}_{T}} {\sum }_{i = 1}^{{n}_{s}} {\sum }_{j = 1}^{{n}_{T}} {k}_{p} ( {f}^{m} ( {X}_{i}^{s} ) , {f}^{m} ( {X}_{j}^{T} ) )$$

kₚ being a Gaussian kernel function.

A sum of Gaussian kernel functions is considered to be a Gaussian kernel function.

P is a natural number greater than or equal to 1 representing the number of Gaussian kernel functions considered for the calculation of the second term.

Let us note MMD_{SSp} the term

$$\frac{1}{{n}_{s}^{2}} {\sum }_{i = 1}^{{n}_{s}} {\sum }_{j = 1}^{{n}_{s}} {k}_{p} ( {f}^{m} ( {X}_{i}^{s} ) , {f}^{m} ( {X}_{j}^{s} ) ) ,$$

with

$${k}_{p} ( {f}^{m} ( {X}_{i}^{s} ) , {f}^{m} ( {X}_{j}^{s} ) )$$

equal to:

$${e}^{\frac{- {\vert {f}^{m} ( {X}_{i}^{s} ) - {f}^{m} ( {X}_{j}^{s} ) \vert}^{2}}{2 {σ}_{mSS ( p )}^{2}} ,}$$

with σ_{mSS}(p) the variance of the Gaussian kernel function kₚ relating to the set f^{m}(X^{S}).

Let us note MMD_{TTp} the term

$$\frac{1}{{n}_{T}^{2}} {\sum }_{i = 1}^{{n}_{T}} {\sum }_{j = 1}^{{n}_{T}} {k}_{p} ( {f}^{m} ( {X}_{i}^{T} ) , {f}^{m} ( {X}_{j}^{T} ) )$$

with

$${k}_{p} ( {f}^{m} ( {X}_{i}^{T} ) , {f}^{m} ( {X}_{j}^{T} ) )$$

equal to:

$${e}^{\frac{- {\vert {f}^{m} ( {X}_{i}^{T} ) - {f}^{m} ( {X}_{j}^{T} ) \vert}^{2}}{2 {σ}_{mTT ( p )}^{2}}}$$

with σ_{mTT}(p) the variance of the Gaussian kernel function kₚ relating to the set f^{m}(X^{T}).

Let us note MMD_{STp} the term

$$\frac{1}{{n}_{s} {n}_{T}} {\sum }_{i = 1}^{{n}_{s}} {\sum }_{j = 1}^{{n}_{T}} {k}_{p} ( {f}^{m} ( {X}_{i}^{s} ) , {f}^{m} ( {X}_{j}^{T} ) )$$

with

$${k}_{p} ( {f}^{m} ( {X}_{i}^{s} ) , {f}^{m} ( {X}_{j}^{T} ) )$$

equal to:

$${e}^{\frac{- {\vert {f}^{m} ( {X}_{i}^{S} ) - {f}^{m} ( {X}_{j}^{T} ) \vert}^{2}}{2 {σ}_{mST ( p )}^{2}}}$$

with σ_{mST}(p) the variance of the Gaussian kernel function kₚ relating to the set f^{m}(X^{S}) and the set f^{m}(X)^{T}.

Thus, MMDₚ(f^{m}(X^{S}), f^{m}(X^{T}))=MMD_{SSp}+MMD_{TTp}−2MMD_{STp}.

Each vector [σ_{mSS}(p)] _{p≥1} is denoted by σ_{mSS}, each vector [σ_{mTT}(p)] _{p≥1} is denoted by σ_{mTT}, each vector [σ_{mST}(p)] _{p≥1} is denoted by σ_{mST}.

In the following, for each layer m ∈Ncc, each matrix

$$( \begin{matrix}{σ}_{mSS} \\ {σ}_{mTT} \\ {σ}_{mST}\end{matrix} )$$

is denoted by σₘ and the set {σₘ}_{m∈Ncc} is denoted by σ. Thus σ is a parameter of the function Σ_{P≥p≥1} Σ_{m∈Ncc} MMDₚ(f^{m}(X^{S}), f^{m}(X^{T})).

The function Σ_{P≥p≥1} Σ_{m∈Ncc} MMDₚ (f^{m}(X^{S}), f^{m}(X^{T})) is a sum of Gaussian kernel functions.

At each of the number M of epochs of training the adaptive neural network, the cost function is minimised, and so the first and second terms of the function are minimised.

The parameter σ is estimated at each epoch of the number of epochs M, before the second term of the cost function is minimised.

Determining the parameter σ comprises a plurality of sub-steps described below.

For each layer m ∈ Ncc, a first sub-step of determining the parameter σ is a sub-step of determining a length Lₘₐₓ, representing the maximum length between the length L_{mT} and the length L_{mS}.

A second step of the estimation method 100 is a step of resampling each signal

$${f}^{m} ( {X}_{i}^{S} )$$

into a two-ummensional image Im_{m,i}^{S} on a grey scale and each signal

$${f}^{m} ( {X}_{j}^{T} )$$

into a two-ummensional image Im_{m,j}^{T} on a grey scale.

Each column of the image Im_{m,i}^{S} comprises a number of pixels equal to \sqrt{Lₘₐₓ} and each row of Im_{m,j}^{S} comprises a number of pixels equal \sqrt{Lₘₐₓ}.

Each column of the vertical image Im_{m,j}^{T} comprises a number of pixels equal \sqrt{Lₘₐₓ} and each row of the image Im_{m,j}^{T} comprises a number of pixels equal to \sqrt{Lₘₐₓ}.

FIG. 2 is a representation of the step of two-dimensionally resampling a signal of the length M.

A second sub-step of determining the parameter σ is a sub-step of constructing a matrix Ng_{√Lmax} . representing a Gaussian kernel of the size \sqrt{Lₘₐₓ}* \sqrt{Lₘₐₓ} and of the variance

$${σ}_{\sqrt{{L}_{m ax}}}$$

from the last row of a Pascal's triangle of the order \sqrt{Lₘₐₓ}.

The matrix Ng_{√Lmax} is constructed from a vector TP_{√Lmax} including \sqrt{Lₘₐₓ} columns and one row and representing the last row of the Pascal's triangle of the order \sqrt{Lₘₐₓ}.

The matrix Ng_{√Lmax} is equal 2^{(1-√Lmax)}*^{t}TP_{√Lmax}*TP_{√Lmax}*2^{(1-√Lmax)}, ^{t}TP_{√Lmax} being the transpose of TP_{√Lmax}.

The matrix Ng_{√Lmax} represents a reproduction of the Gaussian kernel of the size \sqrt{Lₘₐₓ}*\sqrt{L_{max,}} the central value of the matrix being the maximum value, the values of said matrix decreasing little by little away from the centre, so as to arrive at the corners of the matrix Ng_{√Lmax} having values equal 1.

For example, for \sqrt{Lₘₐₓ}=5, the last row of a Pascal's triangle of the order 5 is the following vector: [1 4 6 4 1].

Thus, for \sqrt{Lₘₐₓ}=5, TP_{√Lmax} is (1 4 6 4 1) and 2^{1-√Lmax}=2⁻⁴=( 1/16).

Thus Ng_{√Lmax} is

$$( 1 / 16 ) * ( \begin{matrix}1 \\ 4 \\ 6 \\ 4 \\ 1\end{matrix} ) * ( 14641 ) * ( 1 / 16 ) = [ \begin{matrix}1 & 4 & 6 & 4 & 1 \\ 4 & 16 & 24 & 16 & 4 \\ 16 & 24 & 36 & 24 & 16 \\ 4 & 16 & 24 & 16 & 4 \\ 1 & 4 & 6 & 4 & 1\end{matrix} ] * \frac{1}{256}$$

The image of a matrix Ng_{√Lmax} representing a Gaussian kernel of the size 28*28 is represented in FIG. 3.

A third sub-step of determining the parameter σ is a sub-step of calculating the variance

$${σ}_{\sqrt{{L}_{ma x}}}$$

of the Gaussian kernel represented by the matrix Ng_{√Lmax}. The matrix Ng_{√Lmax} represents the Gaussian kernel of the following formula:

$$G ( x , y ) = \frac{1}{2 π ( σ {\sqrt{{L}_{max} )}}^{2}} {e}^{- \frac{{x}^{2} + {y}^{2}}{2 {( σ \sqrt{{L}_{max}} )}^{2}}} .$$

The function G(x,y) is maximal when the exponential term tends towards 1, thus and is

$${G ( x , y )}_{max} = \frac{- 1}{2 {π ( σ \sqrt{{L}_{max}} )}^{2}} .$$

Let us note max (Ng_{√Lmax}) the maximum value of the matrix Ng_{√Lmax}, thus,

$$G ( x , y ) = max \frac{1}{2 {π ( σ \sqrt{{L}_{max}} )}^{2}} = max ( Ng √ Lmax ) ,$$

which yields:

$$σ \sqrt{{L}_{max}} = \sqrt{\frac{1}{2 π * max ( Ng √ Lmax )}} .$$

$${σ}_{\sqrt{{L}_{ma x}}}$$

does not depend on the training epoch, thus,

$${σ}_{\sqrt{{L}_{ma x}}}$$

can be calculated only for the first epoch and then reused for each of the number of epochs

M, or recalculated for each epoch.

A fourth sub-step of determining the parameter σ is a sub-step of calculating a matrix

$$( \begin{matrix}{σ}_{SS} \\ {σ}_{TT} \\ {σ}_{ST}\end{matrix} ) .$$

σ_{SS} is calculated from the formula:

$$\frac{1}{{n}_{s}^{2}} {\sum }_{i = 1}^{n s} {\sum }_{j = 1}^{n s} {( {Im}_{m , i}^{S} - {Im}_{m , j}^{S} )}^{2} .$$

σ_{TT} is calculated from the formula:

$$= \frac{1}{{n}_{T}^{2}} {\sum }_{i = 1}^{n T} {\sum }_{j = 1}^{n T} {( {Im}_{m , i}^{T} - {Im}_{m , j}^{T} )}^{2} .$$

σ_{ST}is calculated from the formula:

$$\frac{1}{{n}_{s} {n}_{T}} {\sum }_{i = 1}^{n s} {\sum }_{j = 1}^{n T} {( {Im}_{m , i}^{S} - {Im}_{m , j}^{T} )}^{2}$$

Preferably,

$${σ}_{SS} = \frac{1}{{n}_{s}^{2}} {\sum }_{i = 1}^{n s} {\sum }_{j = 1}^{n s} {( {Im}_{m , i}^{s} - {Im}_{m , j}^{s} )}^{2} ⋆ [ 1248 … {2}^{P - 1} ] .$$

Each coefficient σ_{SS}(p) of the matrix σ_{SS}is equal to

$${2}^{p - 1} * \frac{1}{{n}_{s}^{2}} {\sum }_{i = 1}^{n s} {\sum }_{j = 1}^{n s} {( {Im}_{m , i}^{s} - {Im}_{m , j}^{s} )}^{2} .$$

Preferably,

$${σ}_{TT} = \frac{1}{{n}_{T}^{2}} {\sum }_{i = 1}^{n T} {\sum }_{j = 1}^{n T} {( {Im}_{m , i}^{T} - {Im}_{m , j}^{T} )}^{2} ⋆ [ 1248 … {2}^{P - 1} ] .$$

Each coefficient σ_{TT}(p) of the matrix σ_{TT} is equal to

$${2}^{P - 1} * \frac{1}{{n}_{T}^{2}} {\sum }_{i = 1}^{n T} {\sum }_{j = 1}^{n T} {( {Im}_{m , i}^{T} - {Im}_{m , j}^{T} )}^{2} .$$

Preferably,

$${σ}_{ST} = \frac{1}{{n}_{s} {n}_{T}} {\sum }_{i = 1}^{n s} {\sum }_{j = 1}^{n T} {( {Im}_{m , i}^{S} - {Im}_{m , j}^{T} )}^{2} ⋆ [ 1248 … {2}^{P - 1} ] .$$

Each coefficient σ_{ST}(p) of the matrix 94 _{ST} is equal to

$${2}^{p - 1 *} = \frac{1}{{n}_{s} {n}_{T}} {\sum }_{i = 1}^{n s} {\sum }_{j = 1}^{n T} {( {Im}_{m , i}^{S} - {Im}_{m , j}^{T} )}^{2} .$$

According to one embodiment, P is equal to 1. Thus, in this embodiment,

$${σ}_{SS} = \frac{1}{{n}_{s}^{2}} {\sum }_{i = 1}^{n s} {\sum }_{j = 1}^{n s} {( {Im}_{m , i}^{S} - {Im}_{m , j}^{S} )}^{2} ,$$

$${σ}_{TT} = \frac{1}{{n}_{T}^{2}} {\sum }_{i = 1}^{n T} {\sum }_{j = 1}^{n T} {( {Im}_{m , i}^{T} - {Im}_{m , j}^{T} )}^{2} and$$

$${σ}_{ST} = \frac{1}{{n}_{S} {n}_{T}} {\sum }_{i = 1}^{n s} {\sum }_{j = 1}^{n T} {( {Im}_{m , i}^{S} - {Im}_{m , j}^{T} )}^{2} .$$

Preferably, P is equal to 5. A number P equal to 5 makes it possible to obtain balance between calculation time of the adaptive cost function and satisfactory accuracy of the estimate of the difference in distributions.

Thus, the matrix

$$( \begin{matrix}{σ}_{SS} \\ {σ}_{TT} \\ {σ}_{ST}\end{matrix} )$$

depends on each training epoch, the set

$$\{ {Im}_{m , i}^{S} \} 1 \leq j \leq nS ,$$

and the set

$$\{ {lm}_{m , j}^{T} \} 1 \leq j \leq nT ,$$

being moditied at each training epoch by the number M of epochs.

The method for estimating the matrix σₘ comprises a step of calculating the matrix σₘ from the product of the variance

$${σ}_{\sqrt{{L}_{ma x}}}$$

and the matrix

$$( \begin{matrix}{σ}_{SS} \\ {σ}_{TT} \\ {σ}_{ST}\end{matrix} )$$

Preferably,

$${σ}_{m} = {σ}_{\sqrt{{L}_{max}}} * ( \begin{matrix}{σ}_{SS} \\ {σ}_{TT} \\ {σ}_{ST}\end{matrix} ) .$$

Thus, the parameter σ equal to the set {σₘ} _{m∈Ncc} is estimated in the preceding sub-steps.

The method 100 comprises a step 103 of using the adaptive artificial neural network trained on each signal of the target database to associate an operating class with said signal.

1. A method for automatically monitoring at least one rotating part of a rotating machine, from an unlabelled database referred to as the target database comprising at least one time signal derived from a distribution T, the time signal being generated from the rotating part, and from a source database comprising a plurality of time signals derived from a distribution S different from the distribution T, each time signal of the source database being generated from a source rotating part of a source rotating machine and being associated with an operating class from a set of operating classes comprising at least a nominal operating class and a faulty operating class, the method comprising:
training a first trained neural network capable of associating an operating class from the set of operating classes with a non-stationary time signal derived from the distribution S, the first neural network comprising a first part for characteristic extraction, and a second part for classification, the artificial neural network being trained based on source data,
training an adaptive artificial neural network according to a number of training epochs M, in order to obtain a trained artificial neural network capable of associating a class from the set of operating classes with a time signal derived from an S and T union distribution, the adaptive neural network comprising a first part for characteristic extraction, corresponding to the first part of the first neural network, and a second part for adapting the distribution S to the distribution T and for classification, the artificial neural network being simultaneously trained on the source and target databases, training being performed by minimising a cost function comprising:
a first term corresponding to the error between the class obtained by the neural network for each signal of the source database and the class associated with said signal of the source database;
a second term calculated from at least one maximum mean discrepancy between a function of the source database and a function of the target database, a maximum mean discrepancy being calculated from at least one Gaussian kernel function of the parameter σ, the parameter σ being estimated from a Pascal's triangle, the parameter σ being relative to a variance of the Gaussian kernel function and being dependent on each training epoch, the Gaussian kernel function, of the order \sqrt{Lₘₐₓ} being determined from the last row of a Pascal's triangle of the size \sqrt{L_{max,}}
using the adaptive artificial neural network trained on each signal in the target database, in order to associate an operating class with said signal.

2. The method according to claim 1, wherein the first part of the adaptive neural network comprises a number of layers N_{c1}, N_{c1} being a natural number greater than or equal to 1, and wherein the second part of the adaptive neural network comprises a number of layers N_{c2}, N_{c2} being a natural number greater than or equal to 1, the second term of the cost function being calculated on one or more layers belonging to the second part of the neural network, and situated before a last layer of the second part.

3. The method according to claim 1, wherein monitoring is carried out for a plurality of n_{T} rotating machine parts and wherein the target database comprises a plurality of signals denoted by
$${X}^{T} = {\{ {X}_{j}^{T} \}}_{1 \leq j \leq n} T .$$

4. The method according to claim 2, wherein the plurality of signals of the source database is denoted by
$${X}^{{S}_{=}} {\{ {X}_{j}^{S} \}}_{1 \leq j \leq nS}$$
and wherein the second term of the cost function is calculated at each epoch from the function Σ_{P≥p≥1} Σ_{m∈Ncc} MMDₚ (fm(X^{S}), fm(X^{T})), the set of signals
$${f}^{m} ( {X}^{S} ) = {\{ {f}^{m} ( {X}_{i}^{S} ) \}}_{1 \leq i \leq nS}$$
represenung the output of the m^{th} layer of the adaptive artificial neural network for an input X^{S}, each signal
$${f}^{m} ( {X}_{i}^{S} )$$
having a length L_{mS}, and the set of signals
$${f}^{m} ( {X}^{T} ) = {\{ {f}^{m} ( {X}_{j}^{T} ) \}}_{1 \leq j \leq n T}$$
representing the output of the m^{th} layer of the adaptive artificial neural network for an input X^{T}, each signal
$${f}^{m} ( {X}_{j}^{T} )$$
having a length L_{mT}, m being an integer included in a set Ncc comprising each layer number of the second part from which a maximum mean discrepancy is calculated, with:
$$- M M {D}_{p} ( {f}^{m} ( {X}^{S} ) , {f}^{m} ( {X}^{T} ) ) = \frac{1}{{n}_{S}^{2}} {\sum }_{i = 1}^{{n}_{s}} {\sum }_{j = 1}^{{n}_{s}} {k}_{p} ( {f}^{m} ( {X}_{i}^{S} ) , {f}^{m} ( {X}_{j}^{S} ) ) + \frac{1}{{n}_{T}^{2}} {\sum }_{i = 1}^{{n}_{T}} {\sum }_{j = 1}^{{n}_{T}} {k}_{p} ( {f}^{m} ( {X}_{i}^{T} ) , {f}^{m} ( {X}_{j}^{T} ) ) - \frac{2}{{n}_{S} {n}_{T}} {\sum }_{i = 1}^{{n}_{s}} {\sum }_{j = 1}^{{n}_{T}} {k}_{p} ( {f}^{m} ( {X}_{i}^{S} ) , {f}^{m} ( {X}_{j}^{T} ) ) ,$$
With:
$${k}_{p} ( {f}^{m} ( {X}_{i}^{S} ) , {f}^{m} ( {X}_{j}^{S} ) ) = {e}^{\frac{- {\vert {f}^{m} ( {X}_{i}^{S} ) - {f}^{m} ( {X}_{j}^{S} ) \vert}^{2}}{2 {σ}_{mSS ( p )}^{2}}}$$
with σ_{mSS}(p) the variance of the Gaussian kernel function kₚ relating to the set f^{m}(X)^{S},
$${k}_{p} ( {f}^{m} ( {X}_{i}^{T} ) , {f}^{m} ( {X}_{j}^{T} ) ) = {e}^{\frac{- {\vert {f}^{m} ( {X}_{i}^{T} ) - {f}^{m} ( {X}_{j}^{T} ) \vert}^{2}}{2 {σ}_{mTT ( p )}^{2}}}$$
with σ_{mTT}(p) the variance of the Gaussian kernel function kₚ relating to the set f^{m}(X^{T})
$${k}_{p} ( {f}^{m} ( {X}_{i}^{S} ) , {f}^{m} ( {X}_{j}^{T} ) ) = {e}^{\frac{- {\vert {f}^{m} ( {X}_{i}^{S} ) - {f}^{m} ( {X}_{j}^{T} ) \vert}^{2}}{2 {σ}_{mST ( p )}^{2}}}$$
with σ_{mST}(p) the variance of the Gaussian kernel function kₚ relating to the set f^{m}(X^{S}) and the set f^{m}(X)^{T}, P being a natural number greater than or equal to 1, each vector [σ_{mSS}(p)]_{p≥1} being denoted by σ_{mSS}, each vector [σ_{mTT}(p)]_{p≥1} being denoted by σ_{mTT}, each vector [σ_{mST}(p)]_{p≥1} being denoted by σ_{mST} and each matrix
$$( \begin{matrix}{σ}_{mSS} \\ {σ}_{mTT} \\ {σ}_{mST}\end{matrix} )$$
being denoted by σₘ, the parameter σ being equal to the set {σₘ}_{m∈Ncc}.

5. The method according to claim 4, wherein training the adaptive neural network is carried out according to a number of epochs M, and wherein, for each epoch of the number of epochs M, the parameter σ={σₘ}_{m∈Ncc} is estimated in the following sub-steps of:
for each layer m ∈ Ncc:
determining Lₘₐₓ, Lmax being the maximum length between the length of each signal of the set
$${\{ {f}^{m} ( {X}_{i}^{S} ) \}}_{1 \leq i \leq n S}$$
and each signal of the set
$$\{ {f}^{m} ( {X}_{j}^{T} ) \} {,}_{1 \leq j \leq n T}$$
resampling each signal
$${f}^{m} ( {X}_{i}^{S} )$$
into a two-dimensional image Im_{m,i}^{S} of the size \sqrt{Lₘₐₓ}*\sqrt{Lₘₐₓ} and resampling each signal
$${f}^{m} ( {X}_{j}^{T} )$$
into a two-annensional image Im_{m,j}^{T} of the size \sqrt{Lₘₐₓ}*\sqrt{L_{max,}}
determining a variance
$${σ}_{\sqrt{{L}_{ma x}}}$$
of a Gaussian kernel function of the order \sqrt{Lₘₐₓ} in the following sub-steps of:
constructing a matrix Ng_{√Lmax} representing a Gaussian kernel of the order \sqrt{L_{max,}} the matrix Ng_{√Lmax} is equal to: 2^{(1-√Lmax)}*^{t}TP_{√Lmax}*TP_{√Lmax}*2^{(1-√Lmax)}, TP_{√Lmax} representing the last row of a Pascal's triangle of the order \sqrt{Lₘₐₓ} and ^{t}TP_{√Lmax} being the transpose of TP_{√Lmax}.
calculating the variance of
$${σ}_{\sqrt{{L}_{ma x}}}$$
from the formula:
$$\sqrt{\frac{1}{2 π * max ( {Ng}_{√ Lmax} )}} ,$$
max(Ng_{√Lmax}) being equal to the maximum value of the matrix Ng_{√Lmax}
calculating a vector
$$( \begin{matrix}{σ}_{SS} \\ {σ}_{TT} \\ {σ}_{ST}\end{matrix} )$$
in the following sub-steps of:
calculating σ_{SS} from
$$\frac{1}{{n}_{s}^{2}} {\sum }_{i = 1}^{n s} {\sum }_{j = 1}^{n s} {( {Im}_{m , i -}^{s} {Im}_{m , j}^{s} )}^{2} ,$$
calculating σ_{TT} from
$$\frac{1}{{n}_{T}} {\sum }_{i = 1}^{n T} {\sum }_{j = 1}^{n T} {( {Im}_{m , i -}^{T} {Im}_{m , j}^{T} )}^{2}$$
calculating σ_{ST} from
$$\frac{1}{{n}_{S} {n}_{T}} {\sum }_{i = 1}^{n T} {\sum }_{j = 1}^{n T} {( {Im}_{m , i -}^{S} {Im}_{m , j}^{T} )}^{2}$$
calculating σₘ according to the following formula:
$${σ}_{m} = {σ}_{\sqrt{{L}_{max}}} * ( \begin{matrix}{σ}_{S S} \\ {σ}_{T T} \\ {σ}_{S T}\end{matrix} ) .$$

6. The method according to claim 5, wherein:
$${σ}_{SS} = \frac{1}{{n}_{s}^{2}} {\sum }_{i = 1}^{n s} {\sum }_{j = 1}^{n s} {( {Im}_{m , i -}^{T} {Im}_{m , j}^{T} )}^{2} * [ \begin{matrix}1 & 2 & 4 & 8 & … & {2}^{P - 1}\end{matrix} ] ,$$
each coefficient σ_{SS}(p) being equal to
$$2 {*}^{p - 1} \frac{1}{{n}_{s}^{2}} {\sum }_{i = 1}^{n s} {\sum }_{j = 1}^{n s} {( {Im}_{m , i}^{S} - {Im}_{m , j}^{S} )}^{2} ,$$
$${σ}_{TT} = \frac{1}{{n}_{{T}^{2}}} {\sum }_{i = 1}^{n T} {\sum }_{j = 1}^{n T} {( {Im}_{m , i}^{T} - {Im}_{m , j}^{T} )}^{2} * [ \begin{matrix}1 & 2 & 4 & 8 & … & {2}^{P - 1}\end{matrix} ] ,$$
each coefficient σ_{TT}(p) being equal to
$${2}^{p - 1} * \frac{1}{{n}_{T}^{2}} {\sum }_{i = 1}^{nT} {\sum }_{j = 1}^{nT} {( {Im}_{m , i}^{T} - {Im}_{m , j}^{T} )}^{2} .$$
$${σ}_{ST} = \frac{1}{{n}_{S} {n}_{T}} {\sum }_{i = 1}^{n s} {\sum }_{j = 1}^{n T} {( {Im}_{m , i}^{S} - {Im}_{m , j}^{T} )}^{2} * [ \begin{matrix}1 & 2 & 4 & 8 & … & {2}^{P - 1}\end{matrix} ] ,$$
each coefficient σ_{ST}(p) being equal to
$${2}^{p - 1} * \frac{1}{{n}_{S} {n}_{T}} {\sum }_{i = 1}^{ns} {\sum }_{j = 1}^{nT} {( {Im}_{m , i}^{S} - {Im}_{m , j}^{T} )}^{2}$$

7. The method according to claim 4, wherein P is equal to 5.

8. A non-transitory computer readable medium comprising instructions which, when the instructions are executed on a computer, cause the same to implement the steps of the method according to claim 1.
